(19) United States
(12) Patent Application Publication
(10) Pub. No.: US 2016/0197155 A1
(43) Pub. Date: Jul. 7, 2016

(54) SILICON CARBIDE SUBSTRATE, SILICON CARBIDE SEMICONDUCTOR DEVICE, AND METHOD FOR MANUFACTURING SILICON CARBIDE SUBSTRATE

(71) Applicant: Sumitomo Electric Industries, Ltd., Osaka-shi (JP)

(72) Inventor: Toru Hiyoshi, Osaka-shi (JP)

(21) Appl. No.: 14/957,243

(22) Filed: Dec. 2, 2015

(30) Foreign Application Priority Data
Jan. 6, 2015 (JP) 2015-000798

(51) Int. Cl. H01L 29/423; H01L 21/04; H01L 21/324; H01L 29/16; H01L 29/66

(52) U.S. Cl. CPC H01L 29/42364; H01L 29/1608; H01L 29/66068; H01L 29/66477; H01L 21/3247; H01L 21/0475; H01L 29/42356

(57) ABSTRACT

A silicon carbide substrate has a silicon carbide epitaxial layer. The silicon carbide epitaxial layer has a first main surface and a second main surface opposite to the first main surface. The silicon carbide epitaxial layer has a thickness of not less than 50 μm in a direction perpendicular to the second main surface. Z_{1/2} centers are in the silicon carbide epitaxial layer at a density of not more than 1×10¹² cm⁻³. A pit has a maximum depth of not more than 5 nm, the pit originating from a threading dislocation or a basal plane dislocation and having an opening at the second main surface.

### BACKGROUND OF THE INVENTION

1. Field of the Invention

The present invention relates to a silicon carbide substrate, a silicon carbide semiconductor device, and a method for manufacturing the silicon carbide substrate.

2. Description of the Background Art

Silicon carbide has high dielectric breakdown electric field strength and is therefore drawing attention as a material for next-generation power semiconductor devices to replace silicon.

### SUMMARY OF THE INVENTION

In order to realize a silicon carbide power semiconductor device having a high breakdown voltage of, for example, not less than 5 kV, a thick silicon carbide epitaxial layer having a thickness of about not less than 50 μm is needed. Point defects, which are called Z_{1/2} centers and originate from carbon vacancy, are in the silicon carbide epitaxial layer. Each of the Z_{1/2} centers has an energy level of Ec (the lowest energy in the conduction band)−0.65 eV. The Z_{1/2} centers are a so-called lifetime killer and decreases carrier lifetime when the density of Z_{1/2} centers becomes high. In particular, in a bipolar semiconductor device, short carrier lifetime does not lead to sufficient conductivity modulation, thus resulting in high on resistance.

T. Hiyoshi, et. al., “Elimination of the Major Deep Levels in n- and p-Type 4H-SiC by Two-Step Thermal Treatment” Appl. Phys Express 2, 2009, 091101 discloses that the density of Z_{1/2} centers is reduced by thermally oxidizing silicon carbide. When thermally oxidizing a surface of a silicon carbide epitaxial layer, silicon in the vicinity of the surface reacts with oxygen, thereby forming a silicon dioxide film. On the other hand, carbon in the vicinity of the surface remains in the silicon carbide epitaxial layer. The carbon thus remaining is recombined with Z_{1/2} centers in the silicon carbide epitaxial layer, thereby eliminating Z_{1/2} centers in the surface layer of the silicon carbide epitaxial layer. When the silicon carbide epitaxial layer is annealed, carbon is diffused to a deep layer of the silicon carbide epitaxial layer. Accordingly, Z_{1/2} centers in the deep layer of the silicon carbide epitaxial layer can be eliminated. As a result, the carrier lifetime of the thick silicon carbide epitaxial layer can be improved.

However, in the case of a silicon carbide semiconductor device employing a thick silicon carbide epitaxial layer having a thickness of, for example, about not less than 50 μm and having Z_{1/2} centers reduced by thermally oxidizing the surface of the silicon carbide epitaxial layer and then performing annealing, the dielectric breakdown resistance of a gate insulating film provided on the silicon carbide epitaxial layer may be deteriorated.

One embodiment of the present invention has an object to provide a silicon carbide substrate, a silicon carbide semiconductor device, and a method for manufacturing the silicon carbide substrate, by each of which carrier lifetime can be improved and dielectric breakdown of a gate insulating film can be suppressed.

A silicon carbide substrate according to one embodiment of the present invention includes a silicon carbide epitaxial layer. The silicon carbide epitaxial layer has a first main surface and a second main surface opposite to the first main surface. The silicon carbide epitaxial layer has a thickness of not less than 50 μm in a direction perpendicular to the second main surface. Z_{1/2} centers are in the silicon carbide epitaxial layer at a density of not more than 1×10¹² cm⁻³. A pit has a maximum depth of not more than 5 nm, the pit originating from a threading dislocation or a basal plane dislocation and having an opening at the second main surface

A method for manufacturing a silicon carbide substrate according to one embodiment of the present invention includes the following steps. A silicon carbide epitaxial substrate is prepared which includes a silicon carbide single crystal substrate on which a silicon carbide epitaxial layer is provided. The silicon carbide epitaxial layer has a first main surface and a second main surface, the first main surface being in contact with the silicon carbide single crystal substrate, the second main surface being opposite to the first main surface. An oxide film is formed in contact with the silicon carbide epitaxial layer by oxidizing the second main surface. A third main surface of the silicon carbide epitaxial layer is exposed by removing the oxide film from the silicon carbide epitaxial layer. The silicon carbide epitaxial substrate is annealed after exposing the third main surface. A fourth main surface of the silicon carbide epitaxial layer is exposed by removing a surface layer including the third main surface after annealing the silicon carbide epitaxial substrate. In the step of forming the oxide film, a pit is formed in the silicon carbide epitaxial layer, the pit originating from a threading dislocation or a basal plane dislocation and having a depth larger than 5 nm. In the step of exposing the fourth main surface, the pit has a maximum depth of not more than 5 nm.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing a configuration of a silicon carbide substrate according to a first embodiment of the present invention.

FIG. 2 is a schematic cross sectional view showing a configuration of a silicon carbide semiconductor device according to a second embodiment of the present invention.

FIG. 3 is a flowchart schematically showing a method for manufacturing a silicon carbide substrate according to a third embodiment of the present invention.

FIG. 4 is a flowchart schematically showing a modification of the method for manufacturing the silicon carbide substrate according to the third embodiment of the present invention.

FIG. 5 is a schematic cross sectional view showing a first step of the method for manufacturing the silicon carbide substrate according to the third embodiment of the present invention.

FIG. 6 is a schematic cross sectional view showing a second step of the method for manufacturing the silicon carbide substrate according to the third embodiment of the present invention.

FIG. 7 is a schematic cross sectional view showing a third step of the method for manufacturing the silicon carbide substrate according to the third embodiment of the present invention.

FIG. 8 is a schematic cross sectional view showing a fourth step of the method for manufacturing the silicon carbide substrate according to the third embodiment of the present invention.

FIG. 9 is a schematic cross sectional view showing a fifth step of the method for manufacturing the silicon carbide substrate according to the third embodiment of the present invention.

FIG. 10 is a schematic cross sectional view showing a sixth step of the method for manufacturing the silicon carbide substrate according to the third embodiment of the present invention.

### DESCRIPTION OF THE PREFERRED EMBODIMENTS

As a result of diligently studying a cause of deteriorated dielectric breakdown resistance of a gate insulating film formed on a silicon carbide substrate having a thick silicon carbide epitaxial layer, the inventor obtained the following knowledge and arrived at one embodiment of the present invention.

In order to diffuse carbon to a deep layer of the thick silicon carbide epitaxial layer, a large amount of carbon atoms need to be freed in the silicon carbide epitaxial layer. A conceivable way to attain this is to increase the thickness of a thermal oxidation film by thermally oxidizing the silicon carbide epitaxial layer for a longer time to consume a large amount of silicon. Normally, threading dislocations and basal plane dislocations are in the silicon carbide epitaxial layer. Silicon carbide around the threading dislocations and basal plane dislocations are oxidized at a rate higher than the rate of oxidizing silicon carbide having no threading dislocations and basal plane dislocations. Accordingly, when the silicon carbide epitaxial layer is annealed, silicon carbide around threading dislocations and basal plane dislocations exposed at the surface of the silicon carbide epitaxial layer is oxidized at a high rate, thereby forming a pit shaped to have an opening at the surface. It is considered that when a gate insulating film is formed on the pit, electric field is concentrated on a portion of the gate insulating film near the pit, with the result that dielectric breakdown of the gate insulating film is likely to take place. In particular, when the depth of the pit is larger than 5 nm, it is considered that the dielectric breakdown of the gate insulating film is likely to take place.

### Description of Embodiments of the Present Invention

First, embodiments of the present invention are listed and described.

(1) A silicon carbide substrate 10 according to one embodiment of the present invention includes a silicon carbide epitaxial layer 12. Silicon carbide epitaxial layer 12 has a first main surface 12b and a second main surface 12d opposite to first main surface 12b. Silicon carbide epitaxial layer 12 has a thickness T1 of not less than 50 μm in a direction perpendicular to second main surface 12d. Z_{1/2} centers 1 are in silicon carbide epitaxial layer 12 at a density of not more than 1×10¹² cm⁻³. A pit 4 has a maximum depth D1 of not more than 5 nm, pit 4 originating from a threading dislocation 2 or a basal plane dislocation 3 and having an opening at second main surface 12d.

It should be noted that the expression “pit 4 having a maximum depth of not more than 5 nm” is intended to indicate that a length from second main surface 12d to the deepest portion of pit 4 is not more than 5 nm in the direction perpendicular to second main surface 12d. Further, in the case where there are a plurality of pits 4 each having an opening at second main surface 12d, the expression is intended to indicate that among the plurality of pits 4, a pit having the largest length from second main surface 12d to the deepest portion of pit 4 has a depth of not more than 5 nm. In other words, the depth of each of pits 4 each having an opening at second main surface 12d is not more than 5 nm.

In accordance with silicon carbide substrate 10 according to (1), pit 4, which originates from threading dislocation 2 or basal plane dislocation 3 and has an opening at second main surface 12d, has a maximum depth of not more than 5 nm. Accordingly, the dielectric breakdown resistance of a gate insulating film to be formed on second main surface 12d can be suppressed from being deteriorated. Moreover, the density of Z_{1/2} centers 1 in silicon carbide epitaxial layer 12 is not more than 1×10¹² cm⁻³. Accordingly, the carrier lifetime can be improved.

(2) Preferably in silicon carbide substrate 10 according to (1), silicon carbide epitaxial layer 12 includes an impurity capable of providing one of p type and n type. The impurity has a concentration of not more than 1×10¹⁵ cm⁻³. Accordingly, the breakdown voltage of the silicon carbide semiconductor device can be improved.

(3) Preferably in silicon carbide substrate 10 according to (1) or (2), a carrier lifetime is not less than 1 microsecond. Accordingly, in the case where a bipolar semiconductor device is manufactured using silicon carbide substrate 10, on resistance can be reduced by an effect of conductivity modulation.

(4) A silicon carbide semiconductor device 100 according to one embodiment of the present invention includes silicon carbide substrate 10 recited in any one of (1) to (3), a gate insulating film 57, and a gate electrode 51. Gate insulating film 57 is provided on second main surface 12d. Gate electrode 51 is provided on gate insulating film 57. Silicon carbide semiconductor device 100 has a breakdown voltage of not less than 6.5 kV.

In accordance with silicon carbide semiconductor device 100 according to (4), pit 4, which originates from threading dislocation 2 or basal plane dislocation 3 and has an opening at second main surface 12d, has a maximum depth of not more than 5 nm. Accordingly, the dielectric breakdown resistance of gate insulating film 57 formed on second main surface 12d can be suppressed from being deteriorated. Moreover, the density of Z_{1/2} centers 1 in silicon carbide epitaxial layer 12 is not more than 1×10¹² cm⁻³. Accordingly, the carrier lifetime can be improved.

(5) A method for manufacturing a silicon carbide substrate 10 according to one embodiment of the present invention includes the following steps. A silicon carbide epitaxial substrate 20 is prepared which includes a silicon carbide single crystal substrate 11 on which a silicon carbide epitaxial layer 12 is provided. Silicon carbide epitaxial layer 12 has a first main surface 12b and a second main surface 12a, first main surface 12b being in contact with silicon carbide single crystal substrate 11, second main surface 12a being opposite to first main surface 12b. An oxide film 5 is formed in contact with silicon carbide epitaxial layer 12 by oxidizing second main surface 12a. A third main surface 12c of silicon carbide epitaxial layer 12 is exposed by removing oxide film 5 from silicon carbide epitaxial layer 12. Silicon carbide epitaxial substrate 20 is annealed after exposing third main surface 12c. A fourth main surface 12d of silicon carbide epitaxial layer 12 is exposed by removing a surface layer 12e including third main surface 12c after annealing silicon carbide epitaxial substrate 20. In the step of forming oxide film 5, a pit 4 is formed in silicon carbide epitaxial layer 12, pit 4 originating from a threading dislocation 2 or a basal plane dislocation 3 and having a depth larger than 5 nm. In the step of exposing fourth main surface 12d, pit 4 has a maximum depth D1 of not more than 5 nm.

In accordance with the method for manufacturing silicon carbide substrate 10 according to (5), the maximum depth of pit 4 is not more than 5 nm in the step of exposing fourth main surface 12d. Accordingly, the dielectric breakdown resistance of gate insulating film 57 formed on fourth main surface 12d can be suppressed from being deteriorated. Moreover, silicon carbide epitaxial substrate 20 is annealed after forming oxide film 5 in contact with silicon carbide epitaxial layer 12 by oxidizing second main surface 12a. Accordingly, the density of Z_{1/2} centers 1 in silicon carbide epitaxial layer 12 can be reduced, thus achieving improved carrier lifetime.

(6) Preferably in the method for manufacturing silicon carbide substrate 10 according to (5), in the step of exposing fourth main surface 12d, chemical mechanical polishing is performed onto third main surface 12c. Accordingly, the maximum depth of pit 4 can be reduced readily.

(7) Preferably in the method for manufacturing silicon carbide substrate 10 according to (5) or (6), oxide film 5 has a thickness T2 of not less than 100 μm in a direction perpendicular to first main surface 12b Accordingly, a large amount of carbon can be supplied to silicon carbide epitaxial layer 12, thereby reducing the density of Z_{1/2} centers in the deep layer of thick silicon carbide epitaxial layer 12.

(8) Preferably in the method for manufacturing silicon carbide substrate 10 according to any one of (5) to (7), after the step of annealing silicon carbide epitaxial substrate 20, the Z_{1/2} centers are in silicon carbide epitaxial layer 12 at a density of not more than 1×10¹² cm⁻³. Accordingly, the carrier lifetime can be improved.

(9) Preferably, the method for manufacturing the silicon carbide substrate 10 according to any one of (5) to (8) further includes a step of forming a carbon film 7 on third main surface 12c after the step of removing oxide film 5 and before the step of annealing silicon carbide epitaxial substrate 20. In the step of annealing silicon carbide epitaxial substrate 20, silicon carbide epitaxial substrate 20 is annealed with carbon film 7 being provided on third main surface 12c. Accordingly, silicon carbide epitaxial substrate 20 is annealed with third main surface 12c being covered with carbon film 7, thereby suppressing carbon from being diffused from third main surface 12c to outside silicon carbide epitaxial layer 12.

(10) Preferably, in the method for manufacturing silicon carbide substrate 10 according to any one of (5) to (9), in the step of annealing silicon carbide epitaxial substrate 20, silicon carbide epitaxial substrate 20 is annealed at not less than 1400° C. and not more than 2000° C. With silicon carbide epitaxial substrate 20 being at not less than 1400° C., carbon can be diffused to a deep layer of silicon carbide epitaxial substrate 20. With silicon carbide epitaxial substrate 20 being at not more than 2000° C., silicon carbide can be suppressed from being sublimated.

### Details of Embodiments of the Present Invention

The following describes embodiments of the present invention with reference to figures. It should be noted that in the below-described figures, the same or corresponding portions are given the same reference characters and are not described repeatedly. Regarding crystallographic indications in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

### First Embodiment

### Silicon Carbide Substrate

First, the following describes a configuration of a silicon carbide substrate 10 according to a first embodiment of the present invention.

As shown in FIG. 1, a silicon carbide substrate 10 according to the present embodiment mainly includes a silicon carbide single crystal substrate 11 and a silicon carbide epitaxial layer 12. Silicon carbide single crystal substrate 11 is made of hexagonal silicon carbide having polytype 4H, for example. Silicon carbide epitaxial layer 12 is provided on silicon carbide single crystal substrate 11. Silicon carbide epitaxial layer 12 has a first main surface 12b in contact with silicon carbide single crystal substrate 11 and a second main surface 12d opposite to first main surface 12b. Silicon carbide epitaxial layer 12 has a thickness T1 of not less than 50 μm in a direction perpendicular to second main surface 12d. Preferably, thickness T1 of silicon carbide epitaxial layer 12 is not less than 100 μm, more preferably, not less than 150 μm, still more preferably, not less than 200 μm, and further preferably, not less than 300 μm.

In silicon carbide epitaxial layer 12, there are a plurality of Z_{1/2} centers 1. A Z_{1/2} center 1 is a point defect originating from carbon vacancy. Z_{1/2} centers 1 are in silicon carbide epitaxial layer 12 at a density of not more than 1×10¹² cm⁻³. Preferably, the density of Z_{1/2} centers 1 is not more than 5×10¹¹ cm⁻³. The density of Z_{1/2} centers 1 can be measured by, for example, a DLTS (Deep Level Transient Spectroscopy) method. It should be noted that the expression “the density of Z_{1/2} centers 1 is not more than 1×10¹² cm⁻³” is intended to indicate that the average value of the density of Z_{1/2} centers 1 is not more than 1×10¹² cm⁻³. For example, ten arbitrary regions in silicon carbide epitaxial layer 12 are measured by DLTS, and then the average value of the density of Z_{1/2} centers 1 in the ten regions is calculated, thereby calculating the density of Z_{1/2} centers 1. At least either of threading dislocations 2 and basal plane dislocations 3 exist in silicon carbide epitaxial layer 12. Threading dislocations 2 may be threading screw dislocations, or may be threading edge dislocations. Basal plane dislocations 3 are dislocations extending in a {0001} plane.

A plurality of pits 4 may exist in second main surface 12d of silicon carbide epitaxial layer 12. Each of pits 4 originates from threading dislocations 2 or basal plane dislocations 3, and has an opening at second main surface 12d In other words, pit 4 is formed to have a width getting wider from the first main surface 12b side to the second main surface 12d side when viewed in a cross section (field of view in a direction parallel to second main surface 12d). In the bottom portion of pit 4, threading dislocations 2 or basal plane dislocations 3 are connected to the deepest portion of pit 4. Pit 4 has a maximum depth D1 of not more than 5 nm. Maximum depth D1 of pit 4 is preferably not more than 4 nm, and is more preferably not more than 3 nm. When viewed in a cross section, pit 4 has a V-like shape, for example.

Preferably, silicon carbide epitaxial layer 12 includes an impurity capable of providing one of p type and n type. The impurity capable of providing p type is aluminum or boron, for example. The impurity capable of providing n type is nitrogen or phosphorus, for example. The impurity has a concentration of, for example, not less than 5×10¹³ cm⁻³ and not more than 1×10¹⁵ cm⁻³. For example, in order to realize a power semiconductor having a breakdown voltage of 6.5 kV, silicon carbide epitaxial layer 12 has a thickness of about not less than 50 μm and not more than 60 μm, and includes nitrogen at a concentration of about not less than 5×10¹⁴ cm⁻³ and not more than 3×10¹⁵ cm⁻³. For example, in order to realize a power semiconductor having a breakdown voltage of 10 kV, silicon carbide epitaxial layer 12 has a thickness of about not less than 80 m and not more than 120 μm and includes nitrogen at a concentration of about not less than 1×10¹⁴ cm⁻³ and not more than 1×10¹⁵ cm⁻³. For example, in order to realize a power semiconductor having a breakdown voltage of 30 kV, silicon carbide epitaxial layer 12 has a thickness of about 300 μm and includes nitrogen at a concentration of about not less than 5×10¹³ cm⁻³ and not more than 5×10¹⁴ cm⁻³.

The type and concentration of the impurity in silicon carbide epitaxial layer 12 can be measured by, for example, SIMS (Secondary Ion Mass Spectrometry). A carrier lifetime is preferably not less than 1 microsecond and is more preferably not less than 1.5 microseconds. A typical carrier lifetime is not more than 0.9 microsecond, for example. The carrier lifetime may be not more than 25 microseconds, for example. The carrier lifetime can be measured by, for example, a μ-PCD (Microwave Photo Conductivity Decay) method. According to the μ-PCD method, excess carriers are generated by providing pulse light to silicon carbide epitaxial layer 12, and conductivity, which is decreased according to recombination of excess carriers, is measured based on reflectance of microwave, thereby finding the carrier lifetime.

Next, the following describes function and effect of silicon carbide substrate 10 according to the first embodiment.

In accordance with silicon carbide substrate 10 according to the first embodiment, pit 4, which originates from threading dislocations 2 or basal plane dislocations 3 and has an opening at second main surface 12d, has a maximum depth D1 of not more than 5 nm. Accordingly, the dielectric breakdown resistance of a gate insulating film to be formed on second main surface 12d can be suppressed from being deteriorated. Moreover, the density of Z_{1/2} centers 1 in silicon carbide epitaxial layer 12 is not more than 1×10¹² cm⁻³. Accordingly, the carrier lifetime can be improved.

Moreover, in accordance with silicon carbide substrate 10 according to the first embodiment, silicon carbide epitaxial layer 12 includes the impurity capable of providing one of p type and n type. The impurity has a concentration of not more than 1×10¹⁵ cm⁻³. Accordingly, the breakdown voltage of the silicon carbide semiconductor device can be improved.

Further, in accordance with silicon carbide substrate 10 according to the first embodiment, the carrier lifetime is not less than 1 microsecond. Accordingly, in the case where a bipolar semiconductor device is manufactured using silicon carbide substrate 10, on resistance can be reduced by an effect of conductivity modulation.

### Second Embodiment

### Silicon Carbide Semiconductor Device

Next, the following describes a configuration of an IGBT (Insulated Gate Bipolar Transistor) as a silicon carbide semiconductor device 100 according to a second embodiment of the present invention.

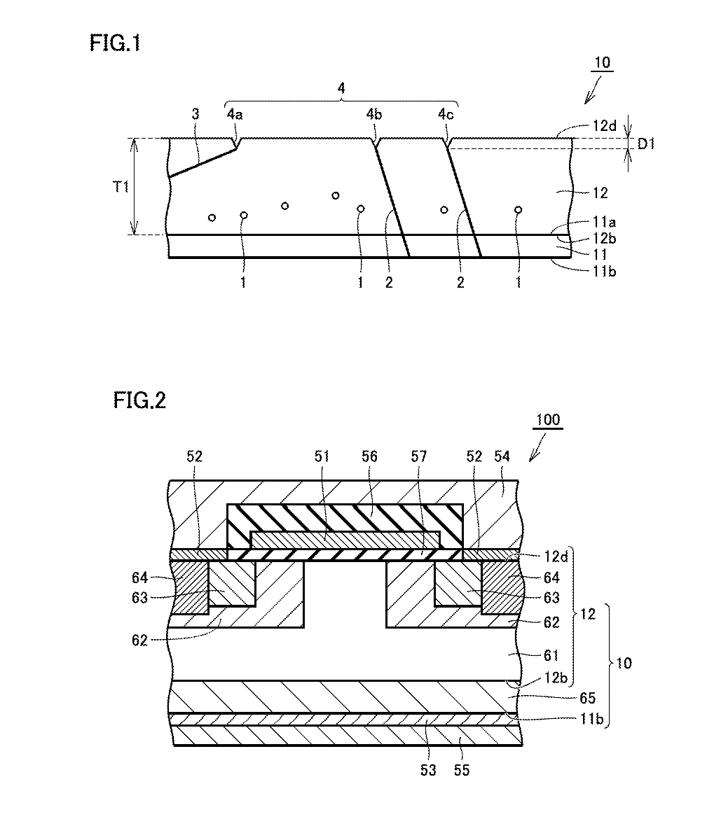

As shown in FIG. 2, IGBT 100 according to the present embodiment is a bipolar semiconductor device mainly including silicon carbide epitaxial layer 12, a gate insulating film 57, a gate electrode 51, an interlayer insulating film 56, an emitter electrode 52, a collector electrode 53, an upper interconnection 54, and a lower interconnection 55. Silicon carbide substrate 10 mainly includes silicon carbide epitaxial layer 12 and a collector region 65.

Silicon carbide epitaxial layer 12 has first main surface 12b and second main surface 12d opposite to first main surface 12b. There are pits 4 in second main surface 12d of silicon carbide epitaxial layer 12, and each of pits 4 originates from threading dislocations 2 or basal plane dislocations 3 and has an opening at second main surface 12d (in FIG. 2, threading dislocations 2, basal plane dislocations 3, and pits 4 are not illustrated). The maximum depth of pit 4 is not more than 5 nm. Silicon carbide epitaxial layer 12 has a thickness of not less than 50 μm in the direction perpendicular to second main surface 12d. The density of Z_{1/2} centers 1 in silicon carbide epitaxial layer 12 is not more than 1×10¹² cm⁻³. IGBT 100 has a breakdown voltage of, for example, not less than 6.5 kV, preferably, not less than 10 kV. The size of pit 4 formed in silicon carbide epitaxial layer 12, the density of Z_{1/2} centers 1 in silicon carbide epitaxial layer 12, the thickness of silicon carbide epitaxial layer 12, and the concentration of the impurity in silicon carbide epitaxial layer 12 are the same as those in the first embodiment.

Silicon carbide epitaxial layer 12 mainly includes a drift region 61, a base region 62, an emitter region 63, and a contact region 64. Drift region 61 includes an n type impurity capable of providing n type such as nitrogen, and has n type (first conductivity type). Base region 62 includes a p type impurity capable of providing p type such as aluminum, and has p type (second conductivity type). Emitter region 63 includes an n type impurity capable of providing n type such as phosphorus, and has n type. Emitter region 63 is separated from drift region 61 by base region 62. Contact region 64 includes a p type impurity capable of providing p type such as aluminum, and has p type (second conductivity type). Contact region 64 extends through emitter region 63 and is in contact with base region 62. The thickness of drift region 61 (i.e., the thickness of silicon carbide epitaxial layer 12) is about 100 μm, for example. The concentration of the n type impurity such as nitrogen in drift region 61 is, for example, about not less than 1×10¹⁵ cm⁻³ and not more than 1×10¹⁵ cm⁻³.

Collector region 65 includes a p type impurity capable of providing p type such as aluminum, and is a silicon carbide epitaxial region having p type (second conductivity type). Collector region 65 is in contact with drift region 61, and is separated from base region 62 by drift region 61. Collector electrode 53 is in contact with collector region 65. For example, collector electrode 53 is in ohmic contact with collector region 65. Lower interconnection 55 is in contact with collector electrode 53. Collector electrode 53 is between collector region 65 and lower interconnection 55.

Gate insulating film 57 is provided on second main surface 12d. In second main surface 12d of silicon carbide epitaxial layer 12, gate insulating film 57 is in contact with emitter region 63, drift region 61, and base region 62. Emitter electrode 52 is in contact with each of emitter region 63 and contact region 64 in second main surface 12d of silicon carbide epitaxial layer 12. Preferably, emitter electrode 52 is in ohmic contact with emitter region 63.

Gate electrode 51 is provided on gate insulating film 57. Gate electrode 51 is provided to face drift region 61, base region 62, and emitter region 63. Interlayer insulating film 56 is provided to cover gate electrode 51. Interlayer insulating film 56 is in contact with each of gate electrode 51 and gate insulating film 57. Upper interconnection 54 is provided to cover interlayer insulating film 56, and is in contact with emitter electrode 52.

It should be noted that the IGBT has been illustrated as an exemplary silicon carbide semiconductor device in the above-described embodiment but the silicon carbide semiconductor device is not limited to the IGBT. For example, the silicon carbide semiconductor device may be: a bipolar semiconductor device such as a BJT (Bipolar Junction Transistor), a PiN diode, a JBS (Junction Barrier Schottky Diode) or a thyristor; or a unipolar semiconductor device such as a MOSFET, a JFET (Junction Field Effect Transistor), or a SBD (Schottky Barrier Diode).

Next, the following describes function and effect of silicon carbide semiconductor device 100 according to the second embodiment.

In accordance with IGBT 100 according to the second embodiment, pit 4, which originates from threading dislocations 2 or basal plane dislocations 3 and has an opening at second main surface 12d, has a maximum depth of not more than 5 nm. Accordingly, the dielectric breakdown resistance of gate insulating film 57 formed on second main surface 12d can be suppressed from being deteriorated. Moreover, the density of Z_{1/2} centers 1 in silicon carbide epitaxial layer 12 is not more than 1×10¹² cm⁻³. Accordingly, the carrier lifetime can be improved.

### Third Embodiment

### Method for Manufacturing Silicon Carbide Substrate

Next, the following describes a method for manufacturing silicon carbide substrate 10 according to a third embodiment of the present invention.

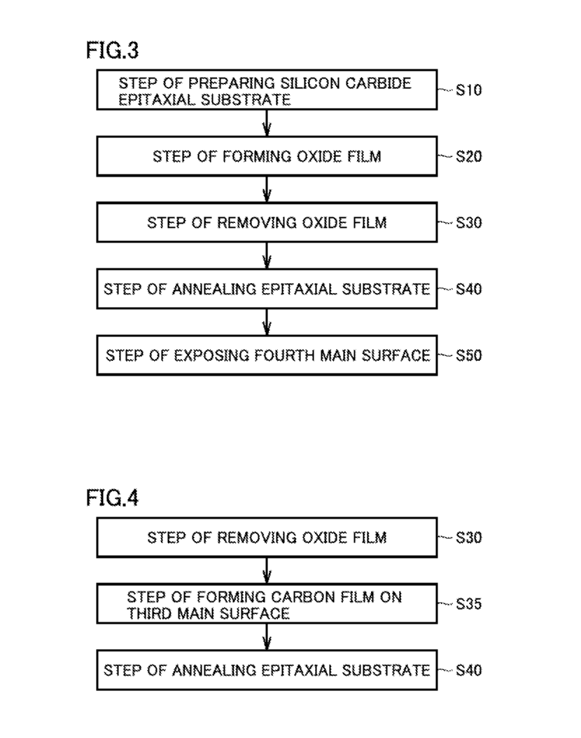

First, a step (S10: FIG. 3) of preparing a silicon carbide epitaxial substrate is performed. For example, silicon carbide single crystal substrate 11 is prepared by slicing a silicon carbide single crystal ingot. The polytype of the silicon carbide is 4H, for example. Silicon carbide single crystal substrate 11 has a front surface 11a and a backside surface 11b, for example. Front surface 11a of silicon carbide single crystal substrate 11 corresponds to a {0001} plane or a plane angled off relative to the {0001} plane, for example. Front surface 11a has an off angle of for example, not less than 1° and not more than 8°, preferably, not less than 2° and not more than 7°, and more preferably, not less than 3° and not more than 5°. The off direction is a <11-20> direction, for example. Silicon carbide single crystal substrate 11 includes an impurity capable of providing n type, such as nitrogen.

Next, silicon carbide epitaxial layer 12 is formed on front surface 11a of silicon carbide single crystal substrate 11. For example, silicon carbide epitaxial layer 12 is grown epitaxially by a CVD (Chemical Vapor Deposition) method. For the epitaxial growth, silane (SiH₄) and propane (C₃H₈) are employed as a source material gas, whereas hydrogen (H₂) is employed as a carrier gas. The temperature of silicon carbide single crystal substrate 11 during the epitaxial growth is about not less than 1400° (and not more than 1700° C. Preferably, an n type impurity such as nitrogen is introduced during the epitaxial growth. The n type impurity has a concentration of, for example, not less than 5×10¹³ cm⁻³ and not more than 1×10¹⁵ cm⁻³. Silicon carbide epitaxial layer 12 has a thickness T1 of, for example, not less than 50 μm in the direction perpendicular to second main surface 12d. Thickness T1 of silicon carbide epitaxial layer 12 is preferably not less than 100 μm, more preferably, not less than 150 μm, still more preferably, not less than 200 μm, and further preferably, not less than 300 μm.

As shown in FIG. 5, threading dislocations 2 or basal plane dislocations 3 may be formed in silicon carbide single crystal substrate 11. Threading dislocations 2 may be threading screw dislocations, and may be threading edge dislocations. Basal plane dislocations 3 are dislocations extending in the {0001} plane. In the epitaxial growth, threading dislocations 2 or basal plane dislocations 3 having been in silicon carbide single crystal substrate 11 are transferred to silicon carbide epitaxial layer 12 and are exposed at second main surface 12a of silicon carbide epitaxial layer 12. Silicon carbide epitaxial layer 12 includes Z_{1/2} centers 1 at a high density. Immediately after the epitaxial growth, the density of Z_{1/2} centers 1 in silicon carbide epitaxial layer 12 is higher than 1×10¹² cm⁻³.

In this way, silicon carbide epitaxial substrate 20 is provided which has silicon carbide single crystal substrate 11 on which silicon carbide epitaxial layer 12 is provided. Silicon carbide epitaxial layer 12 has first main surface 12b in contact with silicon carbide single crystal substrate 11, and second main surface 12a opposite to first main surface 12b (see FIG. 5).

Next, a step (S20: FIG. 3) of forming an oxide film is performed. Specifically, under an oxygen atmosphere, silicon carbide epitaxial substrate 20 is heated at a temperature of not less than 1300° C. for not less than 5 hours, for example. Accordingly, second main surface 12a of silicon carbide epitaxial substrate 20 is oxidized, thereby forming an oxide film 5 in contact with silicon carbide epitaxial layer 12 (see FIG. 6). Oxide film 5 includes silicon dioxide, for example. When forming oxide film 5 by thermally oxidizing second main surface 12a, silicon in the vicinity of second main surface 12a of silicon carbide epitaxial layer 12 reacts with oxygen to obtain silicon dioxide. On the other hand, in silicon carbide epitaxial layer 12, released carbon is combined with Z_{1/2} centers 1 in silicon carbide epitaxial layer 12. When Z_{1/2} centers 1 are recombined with carbon, Z_{1/2} centers 1 are eliminated. Oxide film 5 has a thickness T2 of, preferably, not less than 100 nm, more preferably, not less than 150 nm in the direction perpendicular to first main surface 12b. Thickness T2 of oxide film 5 is not more than 750 nm, for example.

As shown in FIG. 6, during oxidization of second main surface 12a of silicon carbide epitaxial substrate 20, silicon carbide around threading dislocations 2 or basal plane dislocations 3 exposed at second main surface 12a is oxidized rapidly, thereby forming pits 4 in second main surface 12a. Second main surface 12a includes: pits 4b, 4c originating from threading dislocations 2, and pits 4a originating from basal plane dislocations 3. Oxide film 5 is grown to fill pits 4. Pit 4 has a depth D2 (in other words, the thickness of oxide film 5 in pit 4) larger than 5 nm. Depth D2 of pit 4 may be not less than 10 nm, or may be not less than 20 nm. Depth D2 of pit 4 is not more than 50 nm, for example.

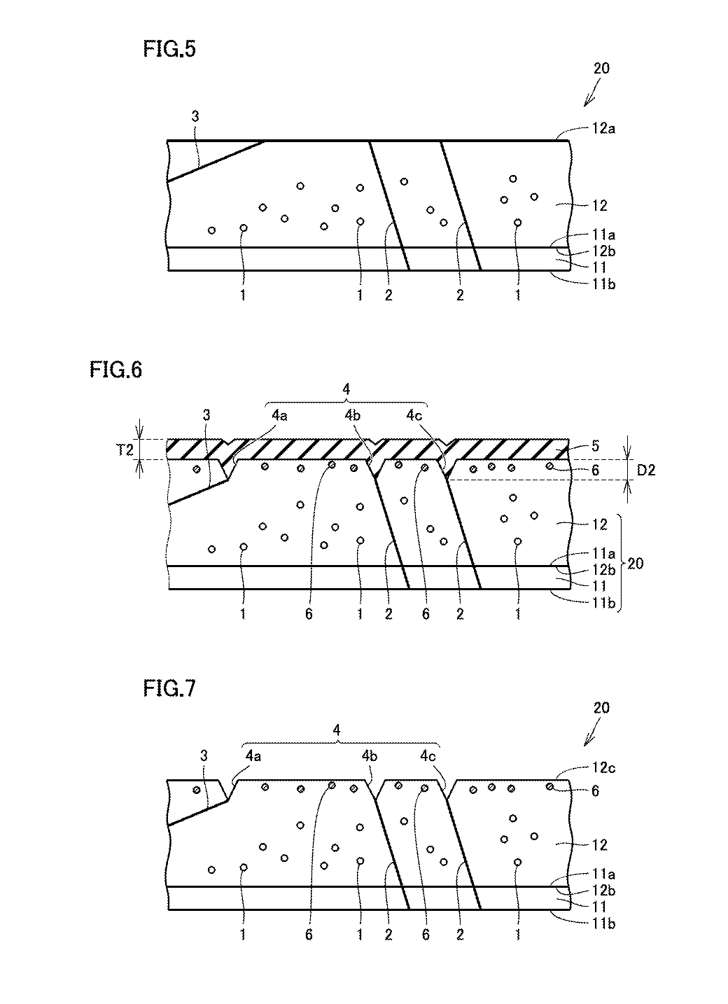

Next, a step (S30: FIG. 3) of removing the oxide film is performed. Specifically, fluoric acid (HF) is employed to remove oxide film 5 from silicon carbide epitaxial substrate 20, for example. Dry etching may be employed to remove oxide film 5 from silicon carbide epitaxial substrate 20. Accordingly, third main surface 12c of silicon carbide epitaxial layer 12 is exposed. Oxide film 5 is removed from inside of pits 4 originating from threading dislocations 2 or basal plane dislocations 3 (see FIG. 7). It should be noted that during the thermal oxidation of second main surface 12a, a surface layer portion of silicon carbide epitaxial layer 12 including second main surface 12a is formed into oxide film 5. Accordingly, third main surface 12c of silicon carbide epitaxial layer 12 as exposed by the removal of oxide film 5 is located at the first main surface 12b side relative to second main surface 12a. As described above, oxide film 5 is removed from silicon carbide epitaxial layer 12 to expose third main surface 12c of silicon carbide epitaxial layer 12.

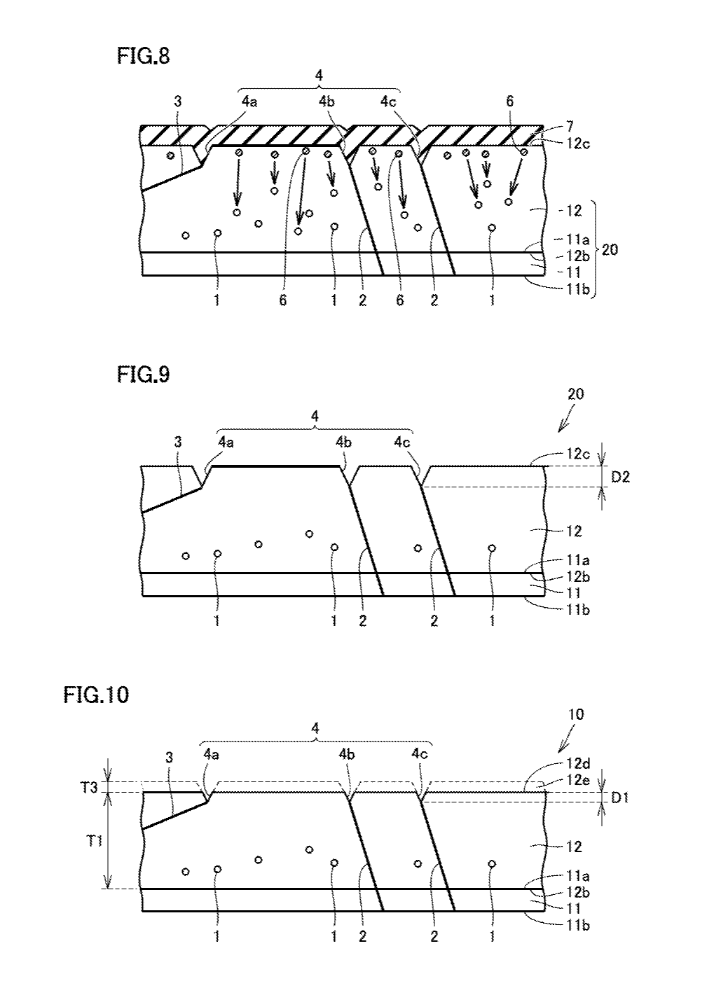

Next, a step (S35: FIG. 4) of forming a carbon film on the third main surface may be performed. For example, a resist is formed on third main surface 12c of silicon carbide epitaxial layer 12. Next, the resist is carbonized in an inert atmosphere such as argon, thereby forming carbon film 7 in contact with third main surface 12c (see FIG. 8). Instead of using the resist, DLC (Diamond-like Carbon) serving as carbon film 7 may be formed on third main surface 12c. Carbon film 7 may be formed to fill pits 4 each having an opening at third main surface 12c. As described above, the step (S35: FIG. 4) of forming the carbon film on the third main surface is performed after the step (S30: FIG. 3) of removing the oxide film and before a step (S40: FIG. 3) of annealing the silicon carbide epitaxial substrate. It should be noted that the step (S35: FIG. 4) of forming the carbon film on the third main surface may be omitted.

Next, the step (S40: FIG. 3) of annealing the silicon carbide epitaxial substrate is performed. For example, silicon carbide epitaxial substrate 20 is annealed at a temperature of not less than 1600° C. for not less than 1 hour. Accordingly, carbon in the vicinity of third main surface 12c is diffused to a deep layer (i.e., the first main surface 12b side) of silicon carbide epitaxial substrate 20. The diffused carbon is recombined with Z_{1/2} centers 1 in the deep layer of silicon carbide epitaxial layer 12, thereby eliminating Z_{1/2} centers 1 in the deep layer. After the step (S40: FIG. 3) of annealing the silicon carbide epitaxial substrate, the density of Z_{1/2} centers in silicon carbide epitaxial layer 12 is, for example, not more than 1×10¹² cm⁻³, preferably, not more than 5×10¹¹ cm⁻³. Preferably, under an inert gas atmosphere such as argon, silicon carbide epitaxial substrate 20 is annealed at not less than 1400° C. and not more than 2000° C. More preferably, silicon carbide epitaxial substrate 20 is annealed at not less than 1500° C. and not more than 1800° C. Preferably, silicon carbide epitaxial substrate 20 is annealed with carbon film 7 being provided on third main surface 12c of silicon carbide epitaxial layer 12.

Next, a step (S50: FIG. 3) of exposing a fourth main surface is performed. The step (S50: FIG. 3) of exposing the fourth main surface is performed after the step (S40: FIG. 3) of annealing the silicon carbide epitaxial substrate. For example, chemical mechanical polishing (CMP) is performed onto third main surface 12c of silicon carbide epitaxial layer 12, thereby removing a surface layer 12e including third main surface 12c (see FIG. 10). Surface layer 12e has a thickness T3 of, for example, not less than 5 nm and not more than 300 nm in the direction perpendicular to first main surface 12b. As slurry for the chemical mechanical polishing, colloidal silica is used, for example. Accordingly, fourth main surface 12d of silicon carbide epitaxial layer 12 is exposed. In the step (S30: FIG. 3) of forming the oxide film, silicon carbide epitaxial layer 12 is provided with pits 4 that originate from threading dislocations 2 or basal plane dislocations 3 and that have a depth larger than 5 nm. In the step (S50: FIG. 3) of exposing the fourth main surface, pits 4 originating from threading dislocations 2 or basal plane dislocations 3 and having a depth larger than 5 nm are subjected to the chemical mechanical polishing until the maximum depth of each pit 4 becomes not more than 5 nm. That is, in the step (S50: FIG. 3) of exposing the fourth main surface, maximum depth D1 of pit 4 becomes not more than 5 nm. It should be noted that pits 4 having a depth larger than 5 nm may be completely removed by the chemical mechanical polishing, or may be partially removed by the chemical mechanical polishing to have a maximum depth of not more than 5 nm.

In the step (S50: FIG. 3) of exposing the fourth main surface, surface layer 12e including third main surface 12c may be removed by performing mechanical polishing (MP) or RIE (Reactive Ion Etching) instead of the chemical mechanical polishing.

It should be noted that in the case where the step (S35: FIG. 4) of forming the carbon film on the third main surface has been performed, fourth main surface 12d may be exposed in the following manner: for example, in the step (S50: FIG. 3) of exposing the fourth main surface, chemical mechanical polishing is employed to remove carbon film 7 so as to expose third main surface 12c and then surface layer 12e including third main surface 12c is removed in a continuous manner (see FIG. 9 and FIG. 10). Alternatively, fourth main surface 12d may be exposed in the following manner: dry etching or wet etching is employed to remove carbon film 7 from above third main surface 12c of silicon carbide epitaxial layer 12 so as to expose third main surface 12c, and then chemical mechanical polishing is employed to remove surface layer 12e including third main surface 12c.

In the above-described embodiment, it has been assumed that n type corresponds to the first conductivity type and p type corresponds to the second conductivity type, however, p type may correspond to the first conductivity type and n type may correspond to the second conductivity type.

Next, the following describes function and effect of the method for manufacturing silicon carbide substrate 10 according to the third embodiment.

In accordance with the method for manufacturing silicon carbide substrate 10 according to the third embodiment, maximum depth D1 of pit 4 is not more than 5 nm in the step of exposing fourth main surface 12d. Accordingly, the dielectric breakdown resistance of gate insulating film 57 formed on fourth main surface 12d can be suppressed from being deteriorated. Moreover, silicon carbide epitaxial substrate 20 is annealed after forming oxide film 5 in contact with silicon carbide epitaxial layer 12 by oxidizing second main surface 12a. Accordingly, the density of Z_{1/2} centers 1 in silicon carbide epitaxial layer 12 can be reduced, thus achieving improved carrier lifetime.

Moreover, in accordance with the method for manufacturing silicon carbide substrate 10 according to the third embodiment, chemical mechanical polishing is performed onto third main surface 12c in the step of exposing fourth main surface 12d. Accordingly, the maximum depth of pit 4 can be reduced readily.

Further, in accordance with the method for manufacturing silicon carbide substrate 10 according to the third embodiment, thickness T2 of oxide film 5 is not less than 100 μm in the direction perpendicular to first main surface 12b. Accordingly, a large amount of carbon can be supplied to silicon carbide epitaxial layer 12, thereby reducing the density of Z_{1/2} centers in the deep layer of thick silicon carbide epitaxial layer 12.

Further, in accordance with the method for manufacturing silicon carbide substrate 10 according to the third embodiment, the density of Z_{1/2} centers in silicon carbide epitaxial layer 12 is not more than 1×10¹² cm⁻³ after the step of annealing silicon carbide epitaxial substrate 20. Accordingly, the carrier lifetime can be improved.

Further, the method for manufacturing silicon carbide substrate 10 according to the third embodiment further includes the step of forming carbon film 7 on third main surface 12c after the step of removing oxide film 5 and before the step of annealing silicon carbide epitaxial substrate 20. In the step of annealing silicon carbide epitaxial substrate 20, silicon carbide epitaxial substrate 20 is annealed with carbon film 7 being provided on third main surface 12c. Accordingly, silicon carbide epitaxial substrate 20 is annealed with third main surface 12c being covered with carbon film 7, thereby suppressing carbon from being diffused from third main surface 12c to outside silicon carbide epitaxial layer 12.

Further, in accordance with the method for manufacturing silicon carbide substrate 10 according to the third embodiment, silicon carbide epitaxial substrate 20 is annealed at not less than 1400° C. and not more than 2000° C. in the step of annealing silicon carbide epitaxial substrate 20. With silicon carbide epitaxial substrate 20 being at not less than 1400° C., carbon can be diffused to a deep layer of silicon carbide epitaxial substrate 20. With silicon carbide epitaxial substrate 20 being at not more than 2000° C., silicon carbide can be suppressed from being sublimated.

### Example

### 1. Preparation of Samples

First, MOSFETs according to samples 1 to 3 were manufactured in the following procedure. Samples 1 and 2 were MOSFETs according to comparative examples, and sample 3 was a MOSFET according to the present example. By thermally oxidizing second main surface 12a of silicon carbide epitaxial substrate 20, oxide film 5 was formed. Next, third main surface 12c of silicon carbide epitaxial substrate 20 was exposed by removing oxide film 5. Next, silicon carbide epitaxial substrate 20 was annealed. Next, surface layer 12e including third main surface 12c was removed by chemical mechanical polishing, thereby exposing fourth main surface 12d of silicon carbide epitaxial substrate 20. Next, gate insulating film 57 was formed on fourth main surface 12d Fourth main surface 12d of the MOSFET according to each of samples 1 to 3 was provided with pits 4 originating from threading dislocations or basal plane dislocations. Pits 4 of the MOSFETs according to samples 1 to 3 respectively had maximum depths of about 30 nm, about 10 nm, and about 5 nm. The specification of the breakdown voltage of each of samples 1 to 3 was set at 1.7 kV.

### 2. Breakdown Voltage Test

A breakdown voltage test was performed with regard to each of the MOSFETs according to samples 1 to 3. In the breakdown voltage test, voltage was applied to the drain electrode with each of the MOSFETs being off. Specifically, voltage between the gate electrode and the source electrode was set at 0 V and voltage between the drain electrode and the source electrode was set at 1700 V. A breakdown voltage test temperature was set at 150° C. Under these breakdown voltage test conditions, time until each of the MOSFETs was broken was measured. It should be noted that in this breakdown voltage test, breakage of a MOSFET resulted from breakage of a gate insulating film in the vicinity of a pit.

### 3. Test Result

TABLE 1

| | | Time until Breakage Started to |
|---|---|---|
| Sample Number | Depth of Pit | Take Place after Start of Test |
| Sample 1 | 30 nm | Around 500 Hours |
| Sample 2 | 10 nm | Around 1000 Hours |
| Sample 3 | 5 nm | No Breakage after Passage of |
| | | Not Less Than 1500 Hours |

Table 1 indicates a relation between the maximum depth of the pit and the time until breakage started to take place after the start of the test. The MOSFET having a pit having a maximum depth of about 30 nm was broken about 500 hours after the start of the test. The MOSFET having a pit having a maximum depth of about 10 nm was broken about 1000 hours after the start of the test. The MOSFET having a pit having a maximum depth of about 5 nm was not broken even about 1500 hours after the start of test. From the results above, it was confirmed that a smaller maximum depth of pit led to a longer time until breakage took place after the start of the test. Moreover, the MOSFET having a pit having a maximum depth of about 5 nm was not broken even about 1500 hours after the start of the test. Hence, the MOSFET having a pit having a maximum depth of less than 5 nm is considered not to be broken even about 1500 hours after the start of the test. In other words, it is considered that by setting the maximum depth of the pit to be not more than 5 nm, the silicon carbide semiconductor device can be suppressed from being deteriorated in dielectric breakdown resistance.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate comprising a silicon carbide epitaxial layer having a first main surface and a second main surface opposite to said first main surface,
said silicon carbide epitaxial layer having a thickness of not less than 50 μm in a direction perpendicular to said second main surface,
Z_{1/2} centers being in said silicon carbide epitaxial layer at a density of not more than 1×10¹² cm⁻³,
a pit having a maximum depth of not more than 5 nm, said pit originating from a threading dislocation or a basal plane dislocation and having an opening at said second main surface.

2. The silicon carbide substrate according to claim 1, wherein
said silicon carbide epitaxial layer includes an impurity capable of providing one of p type and n type, and
said impurity has a concentration of not more than 1×10¹⁵ cm⁻³.

3. The silicon carbide substrate according to claim 1, wherein a carrier lifetime is not less than 1 microsecond.

4. A silicon carbide semiconductor device comprising:
the silicon carbide substrate recited in claim 1;
a gate insulating film provided on said second main surface; and
a gate electrode provided on said gate insulating film,
the silicon carbide semiconductor device having a breakdown voltage of not less than 6.5 kV.

5. A method for manufacturing a silicon carbide substrate comprising steps of:
preparing a silicon carbide epitaxial substrate including a silicon carbide single crystal substrate on which a silicon carbide epitaxial layer is provided, said silicon carbide epitaxial layer having a first main surface and a second main surface, said first main surface being in contact with said silicon carbide single crystal substrate, said second main surface being opposite to said first main surface;
forming an oxide film in contact with said silicon carbide epitaxial layer by oxidizing said second main surface;
exposing a third main surface of said silicon carbide epitaxial layer by removing said oxide film from said silicon carbide epitaxial layer;
annealing said silicon carbide epitaxial substrate after the step of exposing said third main surface; and
exposing a fourth main surface of said silicon carbide epitaxial layer by removing a surface layer including said third main surface after the step of annealing said silicon carbide epitaxial substrate,
in the step of forming said oxide film, a pit being formed in said silicon carbide epitaxial layer, said pit originating from a threading dislocation or a basal plane dislocation and having a depth larger than 5 nm,
in the step of exposing said fourth main surface, said pit having a maximum depth of not more than 5 nm.

6. The method for manufacturing the silicon carbide substrate according to claim 5, wherein in the step of exposing said fourth main surface, chemical mechanical polishing is performed onto said third main surface.

7. The method for manufacturing the silicon carbide substrate according to claim 5, wherein said oxide film has a thickness of not less than 100 μm in a direction perpendicular to said first main surface.

8. The method for manufacturing the silicon carbide substrate according to claim 5, wherein after the step of annealing said silicon carbide epitaxial substrate, Z_{1/2} centers are in said silicon carbide epitaxial layer at a density of not more than 1×10¹² cm⁻³.

9. The method for manufacturing the silicon carbide substrate according to claim 5, further comprising a step of forming a carbon film on said third main surface after the step of removing said oxide film and before the step of annealing said silicon carbide epitaxial substrate, wherein
in the step of annealing said silicon carbide epitaxial substrate, said silicon carbide epitaxial substrate is annealed with said carbon film being provided on said third main surface.

10. The method for manufacturing the silicon carbide substrate according to claim 5, wherein in the step of annealing said silicon carbide epitaxial substrate, said silicon carbide epitaxial substrate is annealed at not less than 1400° C. and not more than 2000° C.
